(19) United States
(12) Patent Application Publication
(10) Pub. No.: US 2020/0233767 A1
(43) Pub. Date: Jul. 23, 2020

(54) DEBUG SYSTEM

(71) Applicants: Chung-Liang Chen, Taipei City (TW); Ping-Cheng Hsieh, Taipei City (TW)

(72) Inventors: Chung-Liang Chen, Taipei City (TW); Ping-Cheng Hsieh, Taipei City (TW)

(73) Assignee: COMPAL ELECTRONICS, INC., Taipei City (TW)

(21) Appl. No.: 16/745,356

(22) Filed: Jan. 17, 2020

Related U.S. Application Data
(60) Provisional application No. 62/793,897, filed on Jan. 18, 2019.

(51) Int. Cl. G06F 11/273; G06F 13/42

(52) U.S. Cl. CPC G06F 11/2733; H03K 19/20; G06F 2213/0042; G06F 13/4282

(57) ABSTRACT

A debug system is provided. The debug system includes a debug card and an electronic device. The debug card displays a debug result corresponding to a debug code. The debug card includes a first port. The first port has a first pin and a second pin. An identification signal having a first logic level is applied to the first pin. The electronic device includes a processor and a second port. The processor performs a debug operation to provide the debug code. The second port has a third pin and a fourth pin. When the second port is electrically connected to the first port, the third pin receives the identification signal and provides the debug code to the first port through the fourth pin according to the identification signal. The second pin receives the debug code.

### CROSS-REFERENCE TO RELATED APPLICATION

This application claims the priority benefit of U.S. provisional application Ser. No. 62/793,897, filed on Jan. 18, 2019. The entirety of the above-mentioned patent application is hereby incorporated by reference herein and made a part of this specification.

### BACKGROUND

### Technical Field

The disclosure relates to a debug system, and more particularly to a debug system capable of obtaining a debug result without disassembling an electronic device.

### Description of Related Art

An electronic device (for example, a desktop computer or a notebook computer) will undergo at least one debug operation during the development verification process to eliminate any abnormal operation of the electronic device. However, the debug result provided by the conventional debug operation can only be obtained by disassembling the electronic device (for example, disassembling the casing of the electronic device). Therefore, the convenience of obtaining the debug result of the debug operation must be improved.

### SUMMARY

The disclosure provides a debug system capable of obtaining a debug result without disassembling an electronic device.

The debug system of the disclosure includes a debug card and an electronic device. The debug card is configured to display a debug result corresponding to a debug code. The debug card includes a first port. The first port has a first pin and a second pin. An identification signal having a first logic level is applied to the first pin. The electronic device includes a processor and a second port. The processor is configured to perform a debug operation to provide the debug code. The second port is coupled to the processor. The second port has a third pin and a fourth pin. When the second port is electrically connected to the first port, the third pin receives the identification signal and provides the debug code to the first port through the fourth pin according to the identification signal. The second pin is configured to receive the debug code.

Based on the above, when the debug card is electrically connected to the electronic device, the second port receives the identification signal through the third pin and provides the debug code to the first port through the fourth pin according to the identification signal. Therefore, the second port may identify that the debug card and the electronic device have completed the electrical connection according to the identification signal. The second port will provide the debug code to the first port through the fourth pin. In this way, the debug system can obtain the debug result without disassembling the electronic device.

To make the aforementioned and other features of the disclosure more comprehensible, several embodiments accompanied with drawings are described in detail as follows.

### BRIEF DESCRIPTION OF THE DRAWINGS

FIG. 1 is a system diagram of a debug system according to an embodiment of the disclosure.

FIG. 2 is a circuit diagram of a second port according to an embodiment of the disclosure.

FIG. 3 is a schematic diagram of a waveform of a debug code and a waveform at a fourth pin according to an embodiment of the disclosure.

### DETAILED DESCRIPTION OF DISCLOSED EMBODIMENTS

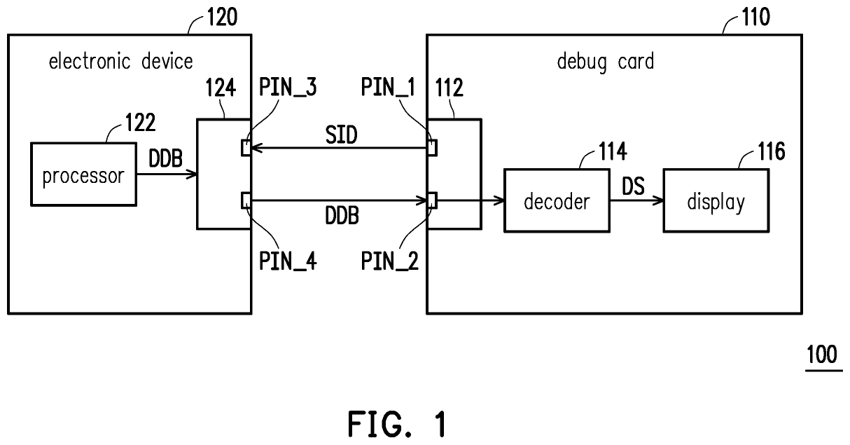

Please refer to FIG. 1. FIG. 1 is a system diagram of a debug system according to an embodiment of the disclosure. In the embodiment, a debug system 100 includes a debug card 110 and an electronic device 120. The electronic device 120 may be, for example, a desktop computer, a notebook computer, or a server. The debug card 110 may be detachably assembled with the electronic device 120 to obtain a debug code DDB and display a debug result corresponding to the debug code DDB. In the embodiment, the debug card 110 includes a first port 112. The first port 112 has at least a first pin PIN_1 and a second pin PIN_2. An identification signal SID having a first logic level is applied to the first pin PIN_1. In the embodiment, the first logic level is a high logic level (the disclosure is not limited thereto). Therefore, the logic level of the first pin PIN_1 will be maintained at a high logic level. The second pin PIN_2 receives the debug code DDB when the debug card 110 is electrically connected to the electronic device 120.

In the embodiment, the electronic device 120 includes a processor 122 and a second port 124. The processor 122 performs a debug operation to provide the debug code DDB. In other words, the processor 122 performs the debug operation on the electronic device 120 to provide the debug code DDB after the debug operation. The second port 124 is coupled to the processor 122. The second port 124 has a third pin PIN_3 and a fourth pin PIN_4. In the embodiment, when the second port 124 is electrically connected to the first port 112 (when the debug card 110 is electrically connected to the electronic device 120), the third pin PIN_3 of the second port 124 is electrically connected to the first pin PIN_1 of the first port 112, and the fourth pin PIN_4 of the second port 124 is electrically connected to the second pin PIN_2 of the first port 112. Therefore, the second port 124 receives the identification signal SID through the third pin PIN_3. The second port 124 provides the debug code DDB to the first port 112 through the fourth pin PIN_4 according to the identification signal SID. In other words, the second port 124 may identify that the debug card 110 and the electronic device 120 have completed the electrical connection according to the identification signal SID. The second port 124 will provide the debug code DDB to the second pin PIN_2 of the first port 112 through the fourth pin PIN_4. In this way, the debug system 100 can obtain the debug result without disassembling the electronic device 120.

On the other hand, in the case where the second port 124 does not receive the identification signal SID, the second port 124 provides a low logic level signal to the first port 112 through the fourth pin PIN_4. In other words, when the second port 124 is electrically connected to an external device other than the debug card 110, the second port 124 does not provide the debug code DDB and provides the low logic level signal.

In the embodiment, the debug card 110 further includes a decoder 114 and a display 116. The decoder 114 is coupled to the second pin PIN_2 to receive the debug code DDB. The decoder 114 decodes the debug code DDB to generate a decode signal DS. The display 116 is coupled to the decoder 114. The display 116 receives the decode signal DS and displays a debug result corresponding to the decode signal DS. In the embodiment, the display 116 may be implemented by at least one seven-segment display, but the disclosure is not limited thereto. In some embodiments, the display 116 may be a display device providing display function, such as a liquid crystal display (LCD), a light-emitting diode (LED) display, an organic light-emitting diode (OLED) display, etc.

In the embodiment, the first port 112 is a universal serial bus (USB). The second port 124 is also a USB. Taking the first port 112 and the second port 124 as USB 3.0 ports as an example, the first pin PIN_1 of the first port 112 is a first ground pin (e.g., a pin GND_DRAIN) in the USB. The second pin PIN_2 of the first port 112 is a second ground pin (e.g., a pin GND) in the USB. The third pin PIN_3 of the second port 124 is a first ground pin (e.g., a pin GND_DRAIN) in the USB. The fourth pin PIN_4 of the second port 124 is a second ground pin (e.g., a pin GND) in the USB. Therefore, when the second port 124 is electrically connected to the first port 112, the first ground pin of the second port 124 is electrically connected to the first ground pin of the first port 112 and the second ground pin of the second port 124 is electrically connected to the second ground pin of the first port 112.

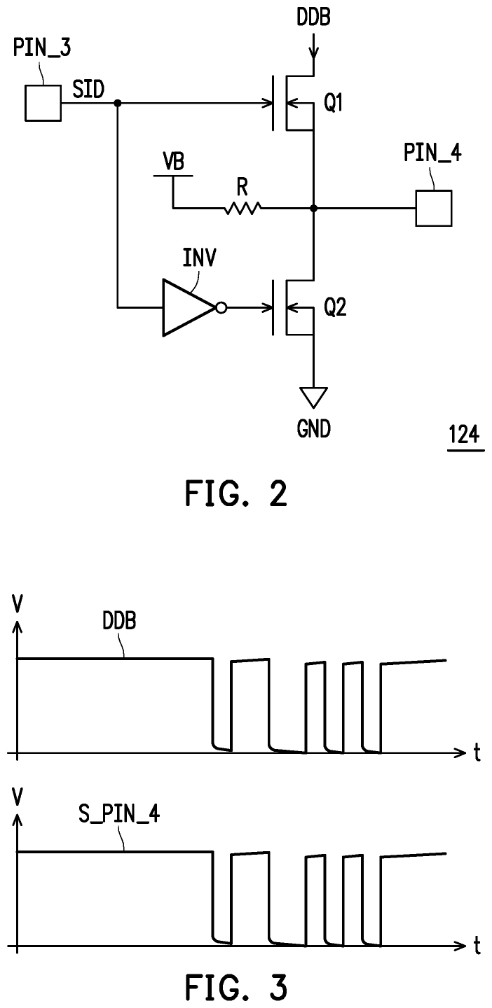

For further explanation, please refer to FIG. 1 and FIG. 2 at the same time. FIG. 2 is a circuit diagram of a second port according to an embodiment of the disclosure. In the embodiment, a second port 124 includes a first transistor Q1, a second transistor Q2, an inverter INV, and a resistor R. A first terminal of the first transistor Q1 is configured to receive the debug code DDB. A second terminal of the first transistor Q1 is coupled to the fourth pin PIN_4. A control terminal of the first transistor Q1 is coupled to the third pin PIN_3. A first terminal of the second transistor Q2 is coupled to the second terminal of the first transistor Q1. A second terminal of the second transistor Q2 is coupled to a reference low voltage (for example, a ground GND). In the embodiment, the first transistor Q1 and the second transistor Q2 are implemented by n-type metal-oxide-semiconductor field-effect transistors (MOSFET), but the disclosure is not limited thereto. In some embodiments, the first transistor Q1 and the second transistor Q2 may be implemented by bipolar transistors (BJT) or thin-film transistors (TFT). An input terminal of inverter INV is coupled to the third pin PIN_3. An output terminal of inverter INV is coupled to a control terminal of the second transistor Q2. The inverter INV performs a logic inversion operation on the signal (the identification signal SID or the low logic level signal) received by the third pin PIN_3. The resistor R is coupled between the reference voltage source VB and the second terminal of the first transistor Q1. The voltage value of the reference voltage source VB of the embodiment is greater than or equal to the voltage value configured to determine a high logic level of, for example, 3.3 volts, but the disclosure is not limited thereto. The resistance value of the resistor R of the embodiment is, for example, 10000 ohms (that is, 10 kΩ), but the disclosure is not limited thereto.

In the embodiment, when the second port 124 is electrically connected to the first port 112, the second port 124 receives the identification signal SID from the first pin PIN_1 through the third pin PIN_3. The identification signal SID has a first logic level (i.e. a high logic level). Therefore, the first transistor Q1 is turned on according to the identification signal SID and the second transistor Q2 is turned off according to the inverted identification signal SID. In this way, the second port 124 may provide the debug code DDB to the first port 112 through the first transistor Q1 and the fourth pin PIN_4. When the logic level of the debug code DDB is a low logic level (for example, the voltage value is 0 volts), the turned-on first transistor Q1 enables the voltage value at the fourth pin PIN_4 to approach 0 volt. The two terminals of the resistor R withstand the voltage difference between the voltage value of the reference voltage source VB and the voltage value at the fourth pin PIN_4. Therefore, when the logic level of the debug code DDB is a low logic level, the logic level at the fourth pin PIN_4 is also a low logic level. When the logic level of the debug code DDB is a high logic level (for example, the voltage value is 3.5 to 3.6 volts), the reference voltage source VB and the resistor R also lift the voltage value at the fourth pin PIN_4. Therefore, when the logic level of the debug code DDB is a high logic level, the logic level at the fourth pin PIN_4 is also a high logic level. At this time, the resistor R may be regarded as a pull-up resistor configured to quickly lift the voltage value of the fourth pin PIN_4.

Please refer to FIG. 1, FIG. 2, and FIG. 3 at the same time. FIG. 3 is a schematic diagram of a waveform of a debug code and a waveform at a fourth pin according to an embodiment of the disclosure. The vertical axis is represented by a voltage value V. The horizontal axis is represented by a time t. In the embodiment, FIG. 3 shows the waveform of the debug code DDB and a waveform S_PIN_4 at the fourth pin PIN_4 when the second port 124 is electrically connected to the first port 112. In the embodiment, the waveform of the debug code DDB and the waveform S_PIN_4 at the fourth pin PIN_4 are synchronized and no distortion occurs. Therefore, when the second port 124 is electrically connected to the first port 112, the second port 124 may effectively provide the debug code DDB to the first port 112.

Please return to the embodiment of FIG. 1 and FIG. 2. On the other hand, when the second port 124 is electrically connected to an external device other than the debug card 110, the logic level of a second pin (e.g., a pin GND) of the external device will be maintained at a low logic level. The first transistor Q1 is turned off and the second transistor Q2 is turned on. Therefore, the turned-on second transistor Q2 pulls down the voltage value of the fourth pin PIN_4 to approach 0 volts. Also, both terminals of the resistor R withstand the voltage difference between the voltage value of the reference voltage source VB and the voltage value at the fourth pin PIN_4. Therefore, the second port 124 does not provide the debug code DDB and provides a low logic level signal. The second pin (e.g., the pin GND) of the external device will receive the low logic level signal for normal operation.

Therefore, based on the above embodiment, the second port 124 may provide a true value table as shown in Table 1.

TABLE 1

| Third pin PIN_3 | Fourth pin PIN_4 |
|---|---|
| H | Debug code DDB |
| L | L |

Where, “H” represents a high logic level and “L” represents a low logic level.

It is worth mentioning here that when the debug card 110 is electrically connected to the electronic device 120, the second port 124 provides the debug code DDB through the fourth pin PIN_4. When the external device is electrically connected to the electronic device 120, the second port 124 provides the low logic level signal through the fourth pin PIN_4. Therefore, based on the circuit configuration of FIG. 2, the function of the second port 124 is switched according to the identification signal SID. In this way, the cost and layout space of adding a switching device (such as a multiplexer or other channel switching integrated circuits) can be saved.

In summary, when the debug card is electrically connected to the electronic device, the second port receives the identification signal through the third pin and provides the debug code to the first port through the fourth pin according to the identification signal. Therefore, the second port may identify that the debug card and the electronic device have completed the electrical connection according to the identification signal. The second port will provide the debug code to the first port through the fourth pin. In this way, the debug system may obtain the debug result without disassembling the electronic device. In addition, the function of the second port is switched according to the identification signal. In this way, the cost and layout space of adding a switching device (such as a multiplexer or other channel switching integrated circuits) can be saved.

Although the disclosure has been disclosed in the above embodiments, the embodiments are not intended to limit the disclosure. It will be apparent to persons skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A debug system, comprising:
a debug card, configured to display a debug result corresponding to a debug code, wherein the debug card comprises:
a first port, having a first pin and a second pin, wherein an identification signal having a first logic level is applied to the first pin; and
an electronic device, comprising:
a processor, configured to perform a debug operation to provide the debug code; and
a second port, coupled to the processor, having a third pin and a fourth pin, wherein when the second port is electrically connected to the first port, the third pin receives the identification signal and provides the debug code to the first port through the fourth pin according to the identification signal, wherein the second pin is configured to receive the debug code.

2. The debug system according to claim 1, wherein the first port is a first universal serial bus (USB), wherein the first pin is a first ground pin of the first USB and the second pin is a second ground pin of the first USB.

3. The debug system according to claim 2, wherein the second port is a second USB, wherein the third pin is a first ground pin of the second USB and the fourth pin is a second ground pin of the second USB.

4. The debug system according to claim 2, wherein when the second port is electrically connected to an external device other than the debug card, a low logic level signal is provided to the first port through the fourth pin.

5. The debug system according to claim 1, wherein when the second port is electrically connected to the first port, the first pin is electrically connected to the third pin and the second pin is electrically connected to the fourth pin.

6. The debug system according to claim 1, wherein the debug card further comprises:
a decoder, coupled to the second pin, configured to receive the debug code and decode the debug code to generate a decode signal.

7. The debug system according to claim 6, wherein the debug card further comprises:
a display, coupled to the decoder, configured to receive the decode signal and display the debug result corresponding to the decode signal.

8. The debug system according to claim 1, wherein the second port comprises:
a first transistor, wherein a first terminal of the first transistor is configured to receive the debug code, a second terminal of the first transistor is coupled to the fourth pin, and a control terminal of the first transistor is coupled to the third pin;
a second transistor, wherein a first terminal of the second transistor is coupled to the second terminal of the first transistor and a second terminal of the second transistor is coupled to a reference low voltage;
an inverter, wherein an input terminal of the inverter is coupled to the third pin and an output terminal of the inverter is coupled to a control terminal of the second transistor; and
a resistor, coupled between a reference voltage source and the second terminal of the first transistor.

9. The debug system according to claim 8, wherein when the second port is electrically connected to the first port, the first transistor is turned on according to the identification signal and the second transistor is turned off according to the inverted identification signal, so that the second port provides the debug code.

10. The debug system according to claim 8, wherein the first logic level is a high logic level.
